(19) United States
(12) Patent Application Publication
(10) Pub. No.: US 2026/0075723 A1
(43) Pub. Date: Mar. 12, 2026

(54) ELECTRONIC MODULE AND METHOD FOR MANUFACTURING ELECTRONIC MODULE

(71) Applicant: Murata Manufacturing Co., Ltd., Kyoto-fu (JP)

(72) Inventors: Toshitaka HAYASHI, Nagaokakyo-shi (JP); Norikazu KUME, Nagaokakyo-shi (JP); Haruhiko IKEDA, Nagaokakyo-shi (JP)

(73) Assignee: Murata Manufacturing Co., Ltd., Kyoto-fu (JP)

(21) Appl. No.: 19/322,215

(22) Filed: Sep. 8, 2025

(30) Foreign Application Priority Data
Sep. 11, 2024 (JP) 2024-157183

(51) Int. Cl. H05K 3/28; H05K 1/18

(52) U.S. Cl. CPC H05K 3/284; H05K 1/181; H05K 3/285; H05K 2201/10431

(57) ABSTRACT

A barrier property that can be expected from the average film thickness of a barrier layer may fail to be achieved. An electronic element includes a component body and a protective film. The protective film includes an organic film covering the outer surface of the component body and containing an organic constituent as a main constituent, and a first barrier film covering the organic film and containing an inorganic constituent as a main constituent. The minimum value of the film thickness of the first barrier film is 15 nm or more, and the maximum value of the film thickness of the first barrier film is 65 nm or less.

### CROSS-REFERENCE TO RELATED APPLICATION

This application claims benefit of priority to Japanese Patent Application No. 2024-157183, filed Sep. 11, 2024, the entire content of which is incorporated herein by reference

### BACKGROUND

### Technical Field

The present disclosure relates to an electronic module and a method for manufacturing an electronic module.

### Background Art

The high barrier film in Japanese Patent No. 6430982 includes a plastic film, an anchor coat layer, a first barrier layer, and a second barrier layer. The anchor coat layer is a layer made of a resin laminated on the plastic film. The respective barrier layers are laminated on the anchor coat layer in the order of the first barrier layer, the second barrier layer, and the first barrier layer. The first barrier layer and the second barrier layer are both layers made of SiOC.

### SUMMARY

In the case of such a high barrier film as disclosed in Japanese Patent No. 6430982, the film thickness of each barrier layer affects the barrier property of the whole high barrier film. However, particularly when the barrier layer has a small film thickness, a barrier property that can be expected from the average film thickness of the barrier layer may fail to be achieved.

Accordingly, an electronic module includes a specific component; an organic film covering an outer surface of the specific component and containing an organic constituent as a main constituent; and a first barrier film directly covering the organic film and containing an inorganic constituent as a main constituent. The film thickness of the first barrier film has a minimum value of 15 nm or more, and the film thickness of the first barrier film has a maximum value of 65 nm or less.

A method for manufacturing an electronic module includes a first film formation step of forming an organic film containing an organic constituent as a main constituent on an outer surface of a specific component; and a second film formation step of forming a first barrier film containing an inorganic constituent as a main constituent on an outer surface of the organic film by an atomic layer deposition method. In the second film formation step, the first barrier film is formed such that the film thickness of the first barrier film has a minimum value of 15 nm or more, and such that the film thickness of the first barrier film has a maximum value of 65 nm or less.

There is an increased possibility of achieving a barrier property depending on the average film thickness of the first barrier layer.

### BRIEF DESCRIPTION OF THE DRAWINGS

FIG. 1 is a sectional view of an electronic module according to a first embodiment;

FIG. 2 is a partial sectional view of the electronic module according to the first embodiment;

FIG. 3 is an enlarged sectional view of a protective layer of the electronic module according to the first embodiment;

FIG. 4 is a flowchart showing each step of a method for manufacturing the electronic module according to the first embodiment;

FIG. 5 is a sectional view of an electronic module according to a second embodiment;

FIG. 6 is a partial sectional view of the electronic module according to the second embodiment;

FIG. 7 is a sectional view of an electronic module according to a third embodiment;

FIG. 8 is a partial sectional view of the electronic module according to the third embodiment;

FIG. 9 is a sectional view of an electronic module according to a fourth embodiment;

FIG. 10 is a partial sectional view of the electronic module according to the fourth embodiment; and

FIG. 11 is a partial sectional view of an electronic module according to a modification example.

### DETAILED DESCRIPTION

Respective embodiments of the electronic module will be described below with reference to the drawings. It is to be noted that constituent elements may be shown in an enlarged manner in the drawings for the sake of easy understanding. The dimensional ratios of the constituent elements may be different from the actual ratios or those in another drawing. In addition, as given as examples in the following respective embodiments, the electronic module refers to a concept including a passive element that electrically or magnetically acts with an electric current applied, an active element that operates with an electric current applied, an assembly with these elements mounted on a wiring board, and the like.

### Configuration of First Embodiment

An embodiment of an electronic element 10 as an electronic module will be described. Examples of the electronic element 10 include an inductor element, a capacitor element, a thermistor element, and a switch element.

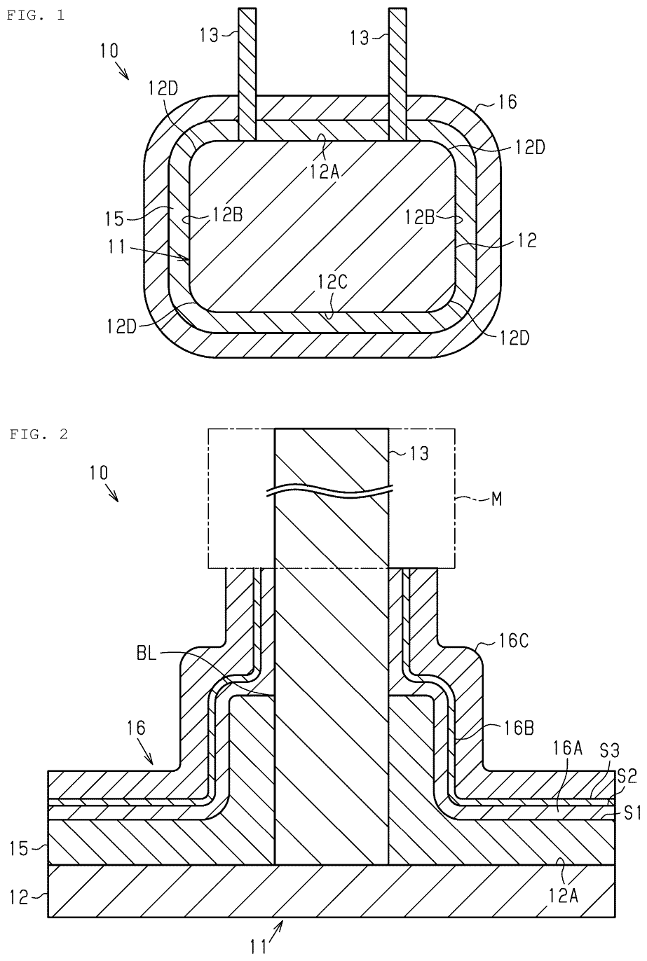

As shown in FIG. 1, the electronic element 10 includes a component body 11 as a specific component. The component body 11 further includes a base body 12 and a pair of external terminals 13. The material of the base body 12 is an insulator. For example, the material of the base body 12 is a ceramic sintered body.

The shape of the base body 12 is generally a rectangular parallelepiped shape. Thus, the base body 12 has six planes as outer surfaces. Hereinafter, a specific one of the six planes of the base body 12 is defined as a first plane 12A. In addition, of the six planes of the base body 12, planes adjacent to the first plane 12A and extending in a direction orthogonal to the first plane 12A are defined as second planes 12B. Thus, the four second planes 12B are present. Furthermore, of the six planes of the base body 12, a plane opposite to the first plane 12A is defined as a third plane 12C. Further, of the outer surface of the base body 12, the part between the respective planes is defined as a ridge part 12D. In this embodiment, the ridge part 12D of the base body 12 is a curved surface part protruding toward the outside of the base body 12. More specifically, the ridge part 12D has a so-called round chamfered shape.

The material of each of the external terminals 13 is a conductive metal. Thus, each of the external terminals 13 is a metal member. Each of the external terminals 13 protrudes from the first plane 12A of the base body 12. Thus, a part of the distal end side for each of the external terminals 13 is exposed to the outside of the base body 12. Further, the base end for each of the external terminals 13 is connected to an external electrode on the surface of the base body 12. Each of the external terminals 13 is connected to internal wiring located in the base body 12 with the external electrode interposed therebetween. It is to be noted that the illustration of: the external electrode on the surface of the base body 12; and the internal terminal in the base body 12 is omitted in FIG. 1. The respective external terminals 13 are disposed at positions spaced apart from each other.

The electronic element 10 includes a sealing material 15. The material of the sealing material 15 is a thermosetting synthetic resin. In addition, the sealing material 15 has an insulating property. Specifically, for example, a polyimide-based resin, an epoxy-based resin, an acrylic-based resin, or the like can be employed as the material of the sealing material 15.

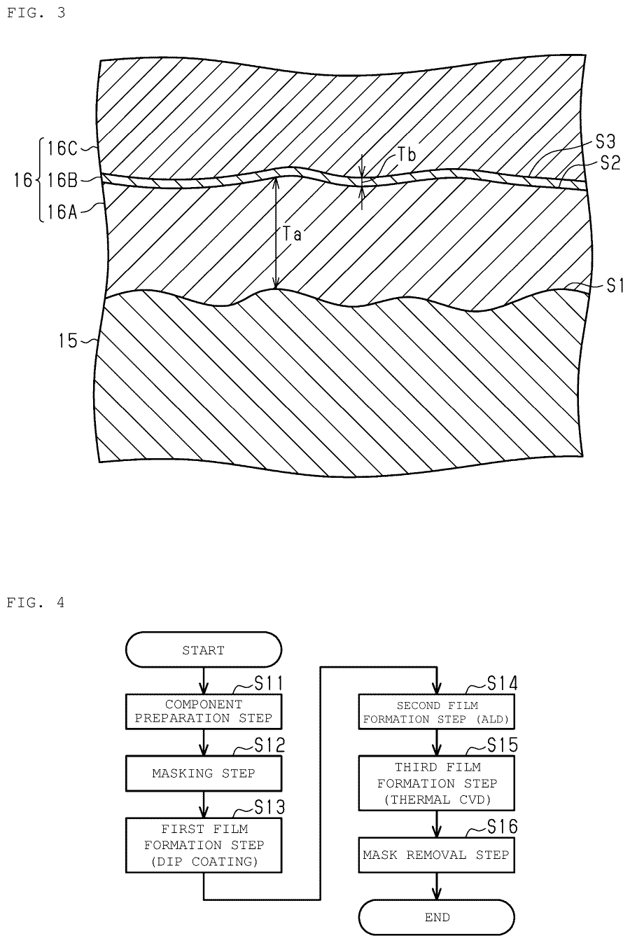

The sealing material 15 covers the entire outer surface of the base body 12. Thus, the sealing material 15 covers not only the first plane 12A, the second planes 12B, and the third plane 12C but also the ridge parts 12D. In addition, the sealing material 15 covers a part of the outer surface of each of the external terminals 13. Specifically, as shown in FIG. 2, the sealing material 15 covers, of the outer surface of each of the external terminals 13, the vicinity of the boundary with the first plane 12A of the base body 12. In contrast, the sealing material 15 does not cover a part of the distal end side for each of the external terminals 13. It is to be noted that in the following, the term “covering” includes not only a case of covering in direct contact, but also a case without direct contact with another member interposed therebetween.

As shown in FIG. 2, the electronic element 10 includes a protective film 16. FIG. 2 is a sectional view of the electronic element 10 in the vicinity of the base end of the external terminal 13. In addition, the shapes of the sealing material 15 and protective film 16 in the vicinity of the base end of the external terminal 13 are illustrated in a simplified fashion in FIG. 1. As shown in FIG. 2, the protective film 16 includes an organic film 16A, a first barrier film 16B, and a second barrier film 16C. More specifically, the protective film 16 has a three-layer structure. Further, these three layers of films are laminated in the order of the organic film 16A, the first barrier film 16B, and the second barrier film 16C as viewed from the sealing material 15. In FIG. 1, the illustration of the three-layer structure of the protective film 16 is omitted, and the protective film 16 is illustrated as if it is a film composed of one layer.

The material of the organic film 16A contains an organic constituent as a main constituent. The organic constituent herein is a constituent including a molecule that has a carbon chain as a main skeleton. Further, the main constituent means that the proportion of the main constituent to the whole is more than 50% by weight. Accordingly, a part of the organic film 16A may have an inorganic constituent as an additive such as a stabilizer or a dispersant. For example, a silicon-containing polyimide, parylene, and the like can be employed as a material of the organic film 16A. In this embodiment, the material of the organic film 16A is a silicon-containing polyimide.

The organic film 16A covers the entire outer surface of the base body 12 from the outside of the sealing material 15. Thus, the organic film 16A covers not only the first plane 12A, the second planes 12B, and the third plane 12C but also the ridge parts 12D. In addition, the organic film 16A covers a part of the outer surface of each of the external terminals 13. Specifically, the organic film 16A covers, of the outer surface of each of the external terminals 13, the boundary BL between the part covered with the sealing material 15 and the part that is not covered with the sealing material 15. In other words, the edge of the organic film 16A is located outside the edge of the sealing material 15. In contrast, the organic film 16A does not cover a part of the distal end side for each of the external terminals 13.

The material of the first barrier film 16B contains an inorganic constituent as a main constituent. The inorganic constituent herein is a constituent that has no carbon chain. Accordingly, a part of the first barrier film 16B may have an organic constituent as an additive such as a stabilizer or a dispersant. Examples of the material of the first barrier film 16B include an aluminum oxide, a titanium oxide, and a hafnium oxide. In this embodiment, the material of the first barrier film 16B is an aluminum oxide.

The first barrier film 16B covers the entire outer surface of the base body 12 from the outside of the organic film 16A. Thus, the first barrier film 16B covers not only the first plane 12A, the second planes 12B, and the third plane 12C but also the ridge parts 12D. Further, the first barrier film 16B directly covers the organic film 16A. In other words, the first barrier film 16B has contact with the organic film 16A. In addition, the first barrier film 16B covers a part of the outer surface of each of the external terminals 13. Specifically, the first barrier film 16B covers, of the outer surface of each of the external terminals 13, the boundary BL between the part covered with the sealing material 15 and the part that is not covered with the sealing material 15. In contrast, the first barrier film 16B does not cover a part of the distal end side for each of the external terminals 13. Further, the edge of the first barrier film 16B coincides with the edge of the organic film 16A. More specifically, the first barrier film 16B directly covers the entire outer surface S2 of the organic film 16A, and at the same time, does not protrude outward with respect to the organic film 16A.

The material of the second barrier film 16C is different from the material of the first barrier film 16B. As the material of the second barrier film 16C, a silicon-containing polyimide, parylene, and the like can be employed. In this embodiment, the material of the second barrier film 16C is parylene.

The second barrier film 16C covers the entire outer surface of the base body 12 from the outside of the first barrier film 16B. Thus, the second barrier film 16C covers not only the first plane 12A, the second planes 12B, and the third plane 12C but also the ridge parts 12D. In addition, the second barrier film 16C covers a part of the outer surface of each of the external terminals 13. Specifically, the second barrier film 16C covers, of the outer surface of each of the external terminals 13, the boundary BL between the part covered with the sealing material 15 and the part that is not covered with the sealing material 15. In contrast, the second barrier film 16C does not cover a part of the distal end side for each of the external terminals 13. The edge of the second barrier film 16C coincides with the edge of the first barrier film 16B and the edge of the organic film 16A. More specifically, the second barrier film 16C directly covers the entire outer surface of the first barrier film 16B, and at the same time, does not protrude outward with respect to the first barrier film 16B or the organic film 16A.

As shown in FIG. 3, the average film thickness of the first barrier film 16B is smaller than the average film thickness of the organic film 16A and the average film thickness of the second barrier film 16C. In addition, the average film thickness of the first barrier film 16B is 50 nm or less. In the first embodiment, the average film thickness of the first barrier film 16B is about 40 nm. In contrast, the average film thickness of the organic film 16A and the average film thickness of the second barrier film 16C are both 1 μm or more. It is to be noted that the illustration of the film thickness Tb of the first barrier film 16B is exaggerated in FIGS. 2 and 3.

Further, the film thickness Ta of the organic film 16A can be measured as follows. First, as shown in FIG. 3, a cross section including the outer surface S1 of the sealing material 15 and the outer surface S2 of the organic film 16A, which is orthogonal to the outer surface S1 of the sealing material 15, is photographed with an electron microscope. Then, an arbitrary site is specified on the surface of the organic film 16A closer to the sealing material 15. It is to be noted that the surface of the organic film 16A closer to the sealing material 15 can be regarded as the same as the outer surface S1 of the sealing material 15. The shortest distance from the arbitrary site to the outer surface S2 of the organic film 16A is defined as the film thickness Ta of the organic film 16A at the arbitrary site. The film thickness Tb of the first barrier film 16B and the film thickness of the second barrier film 16C can also be measured in the same manner.

Furthermore, the average film thickness of the organic film 16A can be measured as follows. In the same manner as described above, a cross section including the outer surface S1 of the sealing material 15 and the outer surface S2 of the organic film 16A, which is orthogonal to the outer surface S1 of the sealing material 15, is photographed with an electron microscope. Next, an observation range in a direction along the outer surface S1 of the sealing material 15 is specified for the photographed electron microscope image. The observation range in this case is 10μm or more. This observation range may be continuously 10μm or more, or the total of ranges at multiple different sites may be 10μm or more. Then, the area of the organic film 16A in the observation range is measured on the electron microscope image by image processing or the like. The value obtained by dividing the calculated area by the length of the observation range is defined as the average film thickness of the organic film 16A. The average film thickness of the first barrier film 16B and the average film thickness of the second barrier film 16C can also be measured in the same manner.

The minimum value of the film thickness Tb of the first barrier film 16B is 15 nm or more. In addition, the maximum value of the film thickness Tb of the first barrier film 16B is 65 nm or less.

The minimum value and maximum value of the film thickness Tb of the first barrier film 16B can be measured as follows. First, a cross section including the outer surface S2 of the organic film 16A and the outer surface S3 of the first barrier film 16B, which is orthogonal to the outer surface S2 of the organic film 16A, is photographed with an electron microscope. Next, an observation range in a direction along the outer surface S1 of the sealing material 15 is specified for the photographed electron microscope image. The observation range in this case is 10μm or more. The minimum value of the film thickness Tb of the first barrier film 16B in the observation range is regarded as the minimum value of the film thickness Tb of the entire first barrier film 16B. Likewise, the maximum value of the film thickness Tb of the first barrier film 16B in the observation range is regarded as the maximum value of the film thickness Tb of the entire first barrier film 16B.

As shown in FIG. 3, the surface roughness of the outer surface S2 of the organic film 16A is smaller than the surface roughness of the surface covered with the organic film 16A, in contact with the organic film 16A. It is to be noted that the surface covered with the organic film 16A, in contact with the organic film 16A, is the outer surface S1 of the sealing material 15 in the first embodiment. The surface roughness of the outer surface S2 of the organic film 16A is preferably 50% or less of the surface roughness of the outer surface S1 of the sealing material 15.

The surface roughness of the outer surface S2 of the organic film 16A can be measured as arithmetic mean roughness. Specifically, a cross section including the outer surface S2 of the organic film 16A, which is orthogonal to the outer surface S1 of the sealing material 15, is photographed with an electron microscope. For the outer surface S2 of the organic film 16A linearly represented on the electron microscope image, the arithmetic mean roughness of the outer surface S2 can be measured by a known calculation method. It is to be noted that the arithmetic mean roughness may be referred to as “Sa (ISO 25178)”, “Ra (JIS B 0601-2001)”, or the like. The surface roughness of the outer surface S1 of the sealing material 15 can also be measured in the same manner.

### Manufacturing Method of First Embodiment

A method for manufacturing the electronic element 10 according to the first embodiment will be described.

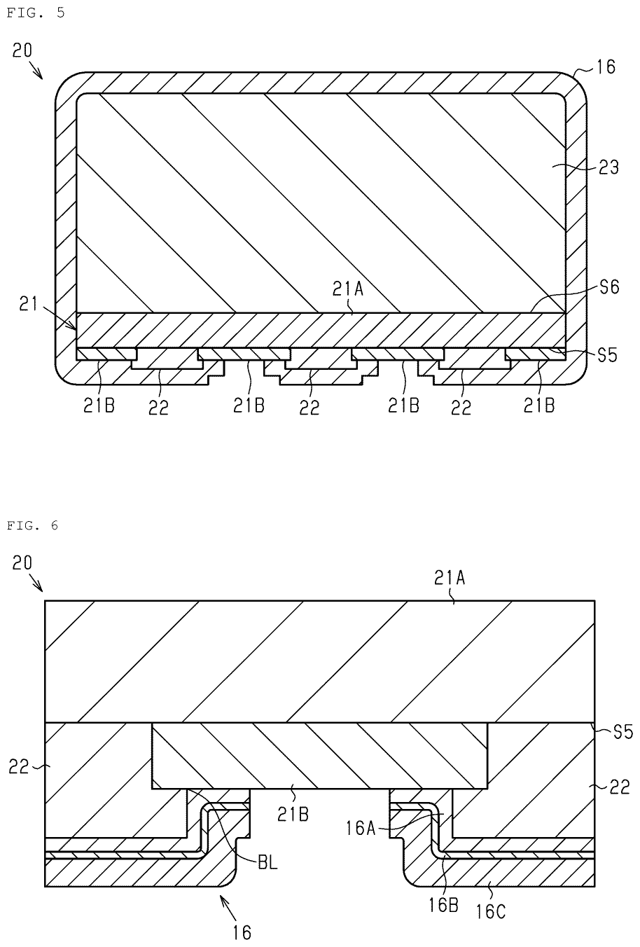

As shown in FIG. 4, the manufacturing method includes a component preparation step S11, a masking step S12, a first film formation step S13, a second film formation step S14, a third film formation step S15, and a mask removal step S16.

In the manufacturing method, first, the component preparation step S11 is carried out. In the component preparation step S11, the component body 11 covered with the sealing material 15 is prepared. Accordingly, the object to be treated in this stage has the base body 12 and respective external terminals 13 of the component body 11, and the sealing material 15.

Next, the masking step S12 is carried out. In the masking step S12, a part of each of the external terminals 13 is covered with a masking tape. Specifically, as shown in FIG. 2, a part of each of the external terminals 13 from the distal end is referred to as a mask region M, and the mask region M is covered with a masking tape. For example, a tape obtained by applying a heat-resistant silicone-based pressure-sensitive adhesive to a surface of a polyimide resin film as a base can be used as the masking tape. It is to be noted that the mask region M in the electronic element 10 is virtually illustrated in FIG. 2.

Next, as shown in FIG. 4, the first film formation step S13 is carried out. In the first film formation step S13, the organic film 16A is formed on the object to be treated by a so-called dip coating method. Specifically, the component body 11 covered with the sealing material 15, which is the object to be treated, is immersed in a coating liquid obtained by dispersing an uncured silicon-containing polyimide in a solvent. In this case, only the base end of each of the external terminals 13 of the component body 11 is brought into contact with the coating liquid. Then, the object to be treated is pulled up from the coating liquid. Thereafter, the object to be treated is heated for several hours. The heating temperature in this case is about 100 degrees or higher and 200 degrees or lower (i.e., from 100 degrees to 200 degrees). Thus, the silicon-containing polyimide is cured, and the solvent and the like are volatilized. As a result, the organic film 16A is formed on the outer surface S1 of the sealing material 15.

Next, the second film formation step S14 is carried out. In the second film formation step S14, the first barrier film 16B is formed on the object to be treated by a so-called atomic layer deposition method (ALD method). Thus, the first barrier film 16B containing an aluminum oxide as a main constituent is formed on the outer surface S2 of the organic film 16A and a part of the outer surface of each of the external terminals 13. As described above, the mask region M of each of the external terminals 13 is covered with the masking tape. Accordingly, the first barrier film 16B is not formed in the mask region M of each of the external terminals 13. In contrast, the organic film 16A covers only a part of the base end side for each of the external terminals 13. Thus, in the stage immediately before the second film formation step S14, an exposed site of each of the external terminals 13 is present between the sealing material 15 and the mask region M for each of the external terminals 13. The first barrier film 16B is also formed on the exposed site of each of the external terminals 13.

Next, the third film formation step S15 is carried out. In the third film formation step S15, the second barrier film 16C is formed on the object to be treated by a so-called chemical vapor deposition method (CVD method). In this embodiment, the second barrier film 16C is formed by a thermal CVD method of forming a film on the object to be treated through a chemical reaction at a high temperature. Thus, the second barrier film 16C containing parylene as a main constituent is formed on the outer surface S3 of the first barrier film 16B. As in the case of the first barrier film 16B, the second barrier film 16C is not formed in the mask region M of each of the external terminals 13.

Next, the mask removal step S16 is performed. In the mask removal step S16, the masking tape attached in the masking step S12 is removed from each of the external terminals 13. Thus, the electronic element 10 is manufactured, with the mask region M for each of the external terminals 13 exposed directly to the outside. Further, the exposed part of each of the external terminals 13 is connected to, for example, an electrode on a substrate with a solder or the like.

### Effects of First Embodiment

The electronic element 10 according to the first embodiment produces the following effects.

(1-1) The first barrier film 16B is expected to have a barrier property corresponding to the average film thickness. The first barrier film 16B may locally have, however, an extremely thin site as compared with the average film thickness. In this case, the barrier property is degraded at the site where the film thickness Tb is small, and thus, the first barrier film 16B as a whole may fail to achieve the barrier property expected depending on the average film thickness. In particular, such a phenomenon is remarkable when the first barrier film 16B has a small average film thickness.

In this regard, according to the first embodiment, the minimum value of the film thickness Tb of the first barrier film 16B is 15 nm or more, and the maximum value of the film thickness Tb of the first barrier film 16B is 65 nm or less. More specifically, the first barrier film 16B is a thin film with the film thickness Tb of 65 nm or less, and at the same time, has a thickness of at least 15 nm or more secured as the film thickness Tb. Thus, there is an increased possibility of achieving a barrier property depending on the average film thickness as the barrier property of the first barrier film 16B.

In addition, the barrier property of the first barrier film 16B is improved basically as the film thickness Tb is increased, but when the film thickness Tb is close to 65 nm, the improvement rate of the barrier property is decreased, thereby reaching the ceiling. Further, when the film thickness Tb exceeds 65 nm, the barrier property of the first barrier film 16B is rather degraded. Accordingly, in the first embodiment, the film thickness of the first barrier film 16B falls within the preferred range in which a high barrier property can be achieved.

(1-2) According to the first embodiment, the organic film 16A and the first barrier film 16B cover the ridge parts 12D of the base body 12. The ridge part 12D is a part corresponding to a so-called corner of the base body 12. Covering the ridge part 12D of the base body 12 with the organic film 16A makes the corner of the base body 12 into a shape chamfered to some extent by the organic film 16A. The presence of the first barrier film 16B on the organic film 16A prevents the film thickness Tb from being extremely reduced at a part of the first barrier film 16B covering the ridge part 12D.

(1-3) According to the first embodiment, the sealing material 15 made from the synthetic resin is provided between the component body 11 and the organic film 16A. The sealing material 15 also prevents moisture and the like from penetrating into the component body 11.

(1-4) According to the first embodiment, the outer surface of each of the external terminals 13 has the boundary BL between the part covered with the sealing material 15 and the part that is not covered with the sealing material 15. At this boundary BL, it is not possible to rule out the possibility that moisture and the like penetrate through the interface between the outer surface of the external terminal 13 and the sealing material 15. According to the first embodiment, the organic film 16A and the first barrier film 16B cover the boundary BL, thus preventing moisture and the like from penetrating through the boundary BL.

(1-5) According to the first embodiment, the average film thickness of the first barrier film 16B is 50 nm or less, and is smaller than the average film thickness of the organic film 16A. In other words, the first barrier film 16B is a very thin film. Accordingly, the presence of the first barrier film 16B can keep the whole size of the electronic element 10 from being increased.

(1-6) According to the first embodiment, the second barrier film 16C that covers the outer surface S3 of the first barrier film 16B is further provided. As a result, the interface between the first barrier film 16B and the second barrier film 16C is produced in the protective film 16. In the presence of the interface as described above, if moisture or the like penetrates into second barrier film 16C, the moisture or the like will spread on the interface, and become less likely to penetrate further into first barrier film 16B. More specifically, in addition to the barrier property of the second barrier film 16C itself, the barrier property can be expected to be also improved by the presence of the interface between the both barrier films.

(1-7) According to the first embodiment, the surface roughness of the outer surface S2 of the organic film 16A is smaller than the surface roughness of the outer surface S1 of the sealing material 15. More specifically, the organic film 16A further flattens irregularities at the surface of the sealing material 15. Further, forming the first barrier film 16B on the outer surface S2 of the flat organic film 16A allows the first barrier film 16B to be kept from varying in the film thickness Tb for each site.

(1-8) According to the first embodiment, the atomic layer deposition method is employed as a film formation method in the second film formation step S14. The atomic layer deposition method is capable of a dense and thin film with a uniform film thickness. More specifically, the method is particularly preferred as a method for forming the first barrier film 16B.

(1-9) According to the first embodiment, the chemical vapor deposition method is employed as a film formation method in the third film formation step S15. The chemical vapor deposition method is more likely to produce a thick film than the atomic layer deposition method. Accordingly, the method is particularly preferred as a film formation method for obtaining the second barrier film 16C with a large thickness and a high barrier property.

### Configuration of Second Embodiment

An embodiment of a package component 20 as an electronic module will be described. It is to be noted that in the second embodiment, the same constituent elements as those in the first embodiment are denoted by the same reference numerals, and the descriptions of the constituent elements may be omitted or simplified.

As shown in FIG. 5, the package component 20 includes a wiring board 21 as a specific component, a solder resist 22 as a sealing material, and a resin molded body 23.

The wiring board 21 further includes a board body 21A and a plurality of wires 21B. The board body 21A has a plate shape. The material of the board body 21A is an insulating synthetic resin such as a phenol resin or an epoxy resin. Each of the wires 21B is located on a first main surface S5 of the board body 21A. The material of each of the wires 21B is a conductive metal. Thus, the wire 21B is a metal member. Although not shown, the wiring board 21 has a plurality of wires inside the board body 21A and on a second main surface S6 on the side opposite to the surface on which the wires 21B are located. The wire 21B is connected to the wire on the second main surface S6 via the wire inside the board body 21A. It is to be noted that the wiring board 21 may be referred to as a printed board or the like.

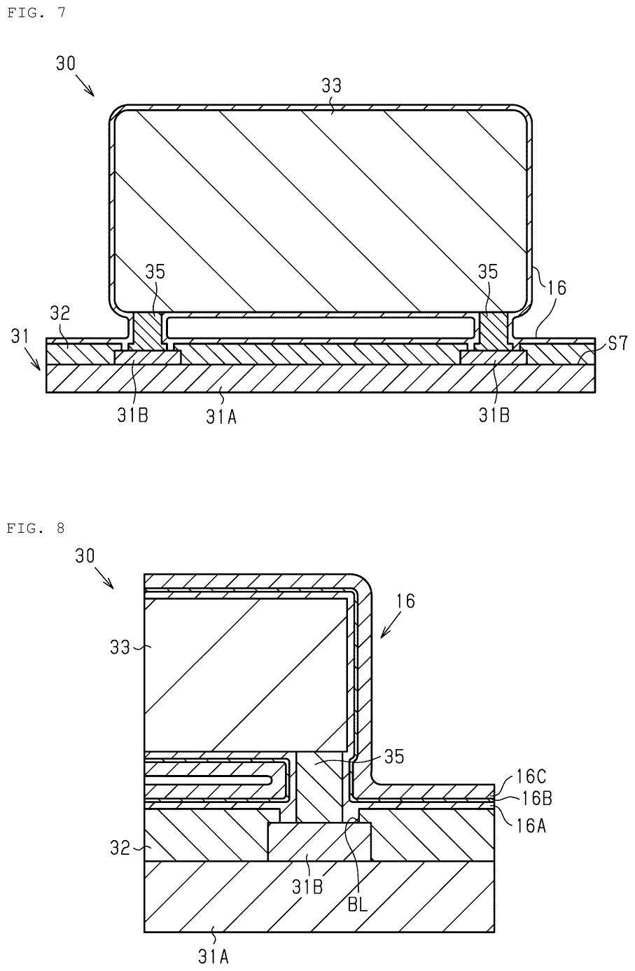

The material of the solder resist 22 is an insulating synthetic resin. The solder resist 22 covers the first main surface S5 of the board body 21A and parts of the wires 21B. Specifically, the solder resist 22 covers, of the first main surface S5 of the board body 21A, the entire region without the wires 21B. In addition, as shown in FIG. 6, the solder resist 22 covers a part of the outer surface of the wire 21B, including the outer edge of the wire 21B, at the end of the wire 21B. Accordingly, the wiring 21B has a part that is not covered with the solder resist 22.

As shown in FIG. 5, resin molded body 23 is located on second main surface S6 of board body 21A. Although not illustrated, resin molded body 23 includes various elements mounted on the second main surface S6 of board body 21A, and an insulating synthetic resin covering these elements. The resin molded body 23 has a substantially rectangular parallelepiped shape. The various elements of the resin molded body 23 are connected to the wires 21B on the first main surface S5 via the wires on second main surface S6 and the wires inside the board body 21A.

As shown in FIG. 5, the package component 20 includes a protective film 16. The protective film 16 covers the outer surface of the resin molded body 23. In addition, the protective film 16 covers parts of the outer surfaces of the wires 21B of the wiring board 21 and the outer surface of the solder resist 22. More specifically, the protective film 16 covers, of the outer surface of the wire 21B, the boundary BL between the part covered with the solder resist 22 and the part that is not covered with the solder resist 22. In contrast, the protective film 16 does not cover a part of the outer surface of the wire 21B. It is to be noted that, of the wiring 21B, the part that is not covered with the protective film 16 functions as a terminal for electrically connecting other electronic elements, substrates, and the like.

As shown in FIG. 6, the protective film 16 includes an organic film 16A, a first barrier film 16B, and a second barrier film 16C in this order as viewed from the object coated with the protective film 16. The film thickness relationship and surface roughness relationship among the respective films of the protective film 16 are the same as those in the first embodiment.

### Effects of Second Embodiment

The package component 20 according to the second embodiment produces the following effects in addition to the same effects as (1-1) and (1-5) to (1-9) of the first embodiment.

(2-1) According to the second embodiment, the outer surface of the wire 21B has the boundary BL between the part covered with the solder resist 22 and the part that is not covered with the solder resist 22. At this boundary BL, it is not possible to rule out the possibility that moisture and the like penetrate through the interface between the outer surface of the wire 21B and the solder resist 22. According to the second embodiment, the protective film 16 covers the boundary BL, thus preventing moisture and the like from penetrating through the boundary BL.

### Configuration of Third Embodiment

An embodiment of a mounting board 30 as an electronic module will be described. The “mounting board” herein refers to a general board that has an electronic element, a chip, and the like mounted. It is to be noted that in the third embodiment, the same constituent elements as those in the first embodiment are denoted by the same reference numerals, and the descriptions of the constituent elements may be omitted or simplified.

As shown in FIG. 7, the mounting board 30 includes a wiring board 31 as a specific component, a solder resist 32 as a sealing material, an electronic element 33, and a joining material 35.

The wiring board 31 further includes a board body 31A and a plurality of wires 31B. The board body 31A has a plate shape. The material of the board body 31A is an insulating synthetic resin such as a phenol resin or an epoxy resin, or silicon. Each of the wires 31B is located on a main surface S7 of the board body 31A. The material of each of the wires 31B is a conductive metal. Thus, the wire 31B is a metal member.

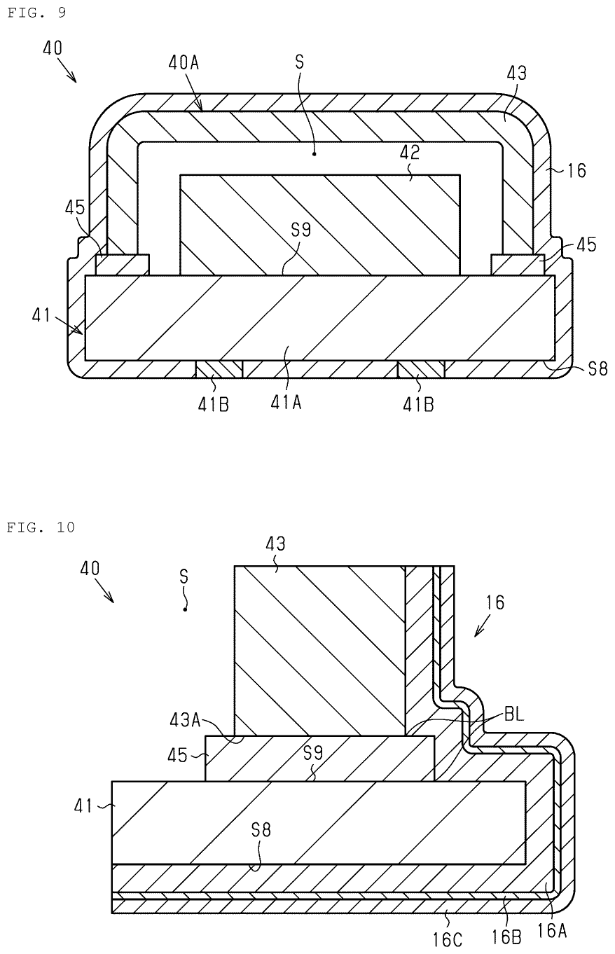

The material of the solder resist 32 is an insulating synthetic resin. The solder resist 32 covers the main surface S7 of the board body 31A and parts of the wires 31B. Specifically, the solder resist 32 covers, of the main surface S7 of the board body 31A, the entire region without the wires 31B. In addition, as shown in FIG. 8, the solder resist 32 covers a part of the outer surface of the wire 31B, including the outer edge of the wire 31B, at the end of the wire 31B. Accordingly, the wiring 31B has a part that is not covered with the solder resist 32. Of the wire 31B, the part that is not covered with the solder resist 32 functions as a terminal for electrically connecting the electronic element 33 and the like.

As shown in FIG. 7, the electronic element 33 is mounted on the wiring board 31. Specifically, the joining material 35 joins an external terminal of the electronic element 33 and the terminal part of the wire 31B, which is not covered with the solder resist 32. It is to be noted that the illustration of the external terminal of the electronic element 33 is omitted in FIG. 7. The joining material 35 is a conductive adhesive or solder. The electronic element 33 is separated from the solder resist 32 on the wiring board 31. Thus, a slight gap is produced between the electronic element 33 and the solder resist 32. It is to be noted that the electronic element 33 herein may have a separate protective film 16 like the electronic element 10 according to the first embodiment, or may have no protective film 16.

As shown in FIG. 7, the mounting board 30 includes a protective film 16. The protective film 16 covers the outer surface of the electronic element 33. More specifically, the protective film 16 covers, of the outer surface of the electronic element 33, the entire region without the joining material 35. In addition, the protective film 16 covers, of the outer surface of the wire 31B, the entire region without the solder resist 32 or the joining material 35. The protective film 16 covers the entire outer surface of the solder resist 32. As a result, the protective film 16 covers, of the outer surface of the wire 31B, the boundary BL between the part covered with the solder resist 32 and the part that is not covered with the solder resist 32. Furthermore, the protective film 16 covers the entire side surfaces of the joining material 35. As described above, the protective film 16 covers the entire region exposed to the outside, of the wires 31B of the wiring board 31, the surface of the solder resist 32, which is closer to the electronic element 33, the electronic element 33, and the outer surfaces of the joining material 35.

As shown in FIG. 8, the protective film 16 includes an organic film 16A, a first barrier film 16B, and a second barrier film 16C in this order as viewed from the object coated with the protective film 16. The film thickness relationship and surface roughness relationship among the respective films of the protective film 16 are the same as those in the first embodiment.

### Effects of Third Embodiment

The mounting board 30 according to the third embodiment produces the following effects in addition to the same effects as (1-1) and (1-5) to (1-9) of the first embodiment.

(3-1) According to the third embodiment, the outer surface of the wire 31B has the boundary BL between the part covered with the solder resist 32 and the part that is not covered with the solder resist 32. At this boundary BL, it is not possible to rule out the possibility that moisture and the like penetrate through the interface between the outer surface of the wire 31B and the solder resist 32. According to the third embodiment, the protective film 16 covers the boundary BL, thus preventing moisture and the like from penetrating through the boundary BL.

(3-2) According to the third embodiment, the part of the outer surface of the electronic element 33, which faces the solder resist 32, and the part of the outer surface of the solder resist 32, which faces the electronic element 33, are also covered with the protective film 16. Furthermore, the side surfaces of the joining material 35 are also covered with the protective film 16. As a result, the wiring board 31, the solder resist 32, the electronic element 33, and the joining material 35 are, as a whole, covered with the continuous protective film 16. Covering the whole with the continuous protective film 16 as described above allows a high barrier property to be achieved.

### Configuration of Fourth Embodiment

An embodiment of a crystal oscillator 40 as an electronic module will be described. It is to be noted that in the fourth embodiment, the same constituent elements as those in the first embodiment are denoted by the same reference numerals, and the descriptions of the constituent elements may be omitted or simplified.

As shown in FIG. 9, the crystal oscillator 40 includes a ceramic board 41 as a first member, a crystal element 42, a metal cap 43 as a second member, and an adhesive 45. The ceramic board 41, the crystal element 42, the metal cap 43, and the adhesive 45 constitute an oscillator body 40A as a specific component.

The ceramic board 41 further includes a board body 41A and a plurality of wires 41B. The board body 41A has a plate shape. The material of the board body 41A is ceramic, specifically silicon. Each of the wires 41B is located on a first main surface S8 of the board body 41A. The material of each of the wires 41B is a conductive metal. Although not shown, the ceramic board 41 has a plurality of wires inside the board body 41A and on a second main surface S9 on the side opposite to the surface on which the wires 41B are located. The wire 41B is connected to the wire on the second main surface S9 via the wire inside the board body 41A.

The crystal element 42 is an element that emits a signal with a prescribed frequency with the use of the piezoelectric effect of a crystal. It is to be noted that a peripheral circuit or the like for supplying power to the crystal element 42 may be mounted on the board body 41A of the ceramic board 41.

An example of the material of the metal cap 43 is stainless steel, an aluminum alloy, or the like. The metal cap 43 has a box shape with one side closed. In other words, the shape of the metal cap 43 is a bottomed box shape. The opening of the metal cap 43 faces the ceramic board 41. The metal cap 43 surrounds the crystal element 42 from the outside.

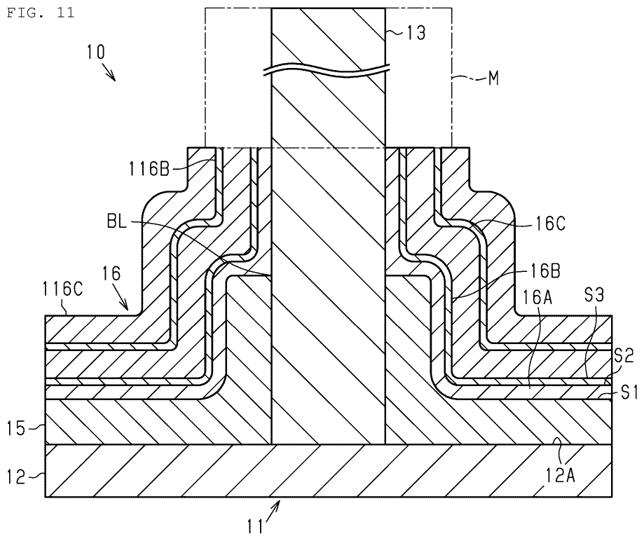

As shown in FIG. 10, the metal cap 43 has an opening edge 43A joined to the second main surface S9 of board body 41A. Specifically, the adhesive 45 joins the opening edge 43A of the metal cap 43 and the second main surface S9 of the board body 41A. The adhesive 45 extends over the entire opening edge 43A of the metal cap 43. The material of the adhesive 45 is a synthetic resin.

As shown in FIG. 9, the crystal oscillator 40 includes a protective film 16. The protective film 16 covers, of the board body 41A, the entire part that is not surrounded by the metal cap 43. It is to be noted that the protective film 16 does not cover a part of the wire 41B. Of the wire 41B, the part that is not covered with the protective film 16 functions as a terminal for electrical connection to a substrate or the like.

The protective film 16 covers the entire outer surface of the metal cap 43. Furthermore, the protective film 16 covers a surface of the adhesive 45 on the side opposite to the space S defined by the metal cap 43. Thus, the protective film 16 covers the boundary BL between the opening edge 43A of the metal cap 43, which is a part covered with the adhesive 45, and a part thereof that is not covered with the adhesive 45. In addition, the protective film 16 covers, of the second main surface S9 of the ceramic board 41, the boundary BL between the part covered with the adhesive 45 and a part that is not covered with the adhesive 45 . As described above, the protective film 16 covers the entire surfaces of the ceramic substrate 41, metal cap 43, and adhesive 45 on the side opposite to the space S, except for parts of the outer surfaces of the wires 41B.

As shown in FIG. 10, the protective film 16 includes an organic film 16A, a first barrier film 16B, and a second barrier film 16C in this order as viewed from the object with the protective film 16 laminated thereon. The film thickness relationship and surface roughness relationship among the respective films of the protective film 16 are the same as those in the first embodiment.

### Effects of Fourth Embodiment

The crystal oscillator 40 according to the fourth embodiment produces the following effects in addition to the same effects as (1-1) and (1-5) to (1-9) of the first embodiment.

(4-1) According to the fourth embodiment, the outer surface of the metal cap 43 has the boundary BL between the opening edge 43A, which is a part covered with the adhesive 45, and the part that is not covered with the adhesive 45. At this boundary BL, it is not possible to rule out the possibility that moisture and the like penetrate through the interface between the outer surface of the metal cap 43 and the adhesive 45. According to the fourth embodiment, the protective film 16 covers the boundary BL, thus preventing moisture and the like from penetrating through the boundary BL. Likewise, the protective film 16 covers, of the second main surface S9 of the ceramic board 41, the boundary BL between the part covered with the adhesive 45 and the part that is not covered with the adhesive 45. Accordingly, moisture and the like are prevented from penetrating through the boundary BL at the ceramic board 41 can be prevented.

### Modification Examples

The above-mentioned embodiments and the following modification examples can be implemented in combination within a range that is not technically contradictory.

The electronic module to which the protective film 16 is applied is not limited to those given as examples in the first to fourth embodiments. The above-described techniques related to the protective film 16 can be applied to various devices such as a passive element, an active element, a substrate, a mounting board obtained by combining the elements and the substrate, and an assembly that has mounting boards integrated.

In the first embodiment, the material and shape of the base body 12 are considered by way of example only. For example, the base body 12 may have a columnar shape or another shape. Further, depending on the shape of the base body 12, the base body 12 may have no clear ridge part 12D. The techniques related to the protective film 16 according to the embodiments mentioned above can be applied also to the base body 12 without such a ridge part 12D. Furthermore, the shape and number of the external terminals 13 can also be changed appropriately in the first embodiment.

For the protective film 16 according to the first embodiment, the edges of the organic film 16A, first barrier film 16B, and second barrier film 16C do not have to coincide with each other. For example, a part of the first barrier film 16B may protrude outward with respect to the organic film 16A, or the edge of the first barrier film 16B may be located inside with respect to the edge of the organic film 16A. In this respect, the same applies to the other films. In the case of shifting the positions of the edges of the respective films in this manner, masking and removal of the masking may be performed for each of film formation steps for the respective films.

In the first embodiment, the edge of the sealing material 15 may coincide with the edge of the protective film 16. When a part of each of the external terminals 13 is subjected to masking in the manufacturing process as in the first embodiment, forming the sealing material 15 up to the part subjected to the masking causes the edge of the sealing material 15 to coincide with the edge of the protective film 16.

In the first embodiment, the sealing material 15 may be omitted. In this case, the protective film 16 directly covers the base body 12 of the component body 11. In addition, in this modification example, the surface roughness of the outer surface S2 of the organic film 16A is preferably smaller than the surface roughness of the outer surface of the base body 12, which is the surface covered with the organic film 16A of the protective film 16 with the surface in contact with the organic film 16A.

The material of the organic film 16A is not limited to those given as examples in the embodiment mentioned above as long as the material contains an organic constituent as a main constituent, and can be changed appropriately. The material may be selected appropriately depending on the barrier property and the like required for the organic film 16A.

The surface roughness of the outer surface S2 of the organic film 16A may be comparable with or more than the surface roughness of the surface covered with the organic film 16A.

The material of the first barrier film 16B is not limited to those given as examples in the embodiment mentioned above as long as the material contains an inorganic constituent as a main constituent, and can be changed appropriately. The material may be selected appropriately depending on the barrier property and the like required for the first barrier film 16B. From the viewpoint of securing the insulating property for the external terminals 13, however, insulating components are preferred among inorganic constituents.

The material of the second barrier film 16C is not limited. The material of the second barrier film 16C is preferably different from the material of the first barrier film 16B in terms of barrier property against a constituent that is different from constituents that can be blocked by the first barrier film 16B as a barrier. However, if the material of the second barrier film 16C is the same as the material of the first barrier film 16B, an interface is produced between both the barrier films. Thus, also in the case of the same material, providing both the first barrier film 16B and the second barrier film 16C has the possibility of enhancing the barrier property.

The second barrier film 16C may be omitted. The presence or absence of the second barrier film 16C may be selected in consideration of the barrier property that can be achieved with the organic film 16A and the first barrier film 16B.

The protective film 16 may have a further barrier layer outside the second barrier film 16C. For example, the first barrier film 16B and the second barrier film 16C outside the first barrier film 16B are regarded as a set of multilayer barrier layers. Multiple sets of multilayer barrier layers may be provided in order as viewed from the organic film 16A. Specifically, as shown in FIG. 11, the protective film 16 may include an organic film 16A, a first barrier film 16B, a second barrier film 16C, a first barrier film 116B, and a second barrier film 116C laminated in this order as viewed from the sealing material 15. It is to be noted that while the protective film 16 that has a five-layer structure has been described with reference to FIG. 11 as a modification example of the first embodiment, the protective film 16 can be similarly modified for the other embodiments.

Another barrier film made of the same material as the first barrier film 16B may be present separately from the first barrier film 16B. In addition, another barrier film made of the same material as first barrier film 16B may directly cover first barrier film 16B. In this case, the part inside the interface between the first barrier film 16B and another barrier film is “the first barrier film 16B directly covering the organic film 16A”. In addition, a different type of barrier film from the first barrier film 16B and the second barrier film 16C may be present.

The average film thickness of the first barrier film 16B is not limited to 50 nm or less given as an example in the first embodiment. It is to be noted that the minimum value of the film thickness Tb of the first barrier film 16B is 15 nm or more, whereas the maximum value of the film thickness Tb of the first barrier film 16B is 65 nm or less. From the foregoing, the average film thickness of the first barrier film 16B can take a value of 15 nm or more and 65 nm or less (i.e., from 15 nm to 65 nm).

The average film thickness of the first barrier film 16B is not necessarily smaller than the average film thickness of the organic film 16A or the average film thickness of the second barrier film 16C. In other words, the average film thickness of the organic film 16A and the average film thickness of the second barrier film 16C may be smaller than the average film thickness of the first barrier film 16B.

The methods for measuring the average film thickness, the film thickness, the minimum value and maximum value of the film thickness, and the surface roughness for each of the films in the first embodiment are considered by way of example only. If there is any unified measurement method defined by various groups and industries, the measurement method may be followed. In addition, a measurement method that is used commonly may be employed depending on the specification of the apparatus or the like.

The method for manufacturing the electronic module, in particular, the method for forming the protective film 16, is not limited to the manufacturing method given as an example in the embodiment above. For example, in each of the first film formation step S13 to the third film formation step S15, a film may be formed by a method other than the method given as an example in the embodiment mentioned above. In addition, in two or more selected from the first film formation step S13 to the third film formation step S15, the same film formation method may be employed.

Furthermore, the masking step S12 may be omitted. In this case, for example, a part of the protective film 16 covering each external terminal 13 may be removed by etching to expose a part of the outer surface of the external terminal 13.

The configuration of the package component 20 according to the second embodiment is considered by way of example, and can be changed appropriately. For example, a plurality of resin molded bodies 23 may be present on the same wiring board 21.

In the second embodiment, the solder resist 22 as a sealing material may be omitted. In this case, the protective film 16 directly covers the first main surface S5 of the board body 21A. In addition, in this modification example, the surface roughness of the outer surface S2 of the organic film 16A is preferably smaller than the surface roughness of the first main surface S5 of the board body 21A, which is the surface covered with the organic film 16A of the protective film 16 with the surface in contact with the organic film 16A.

The configuration of the mounting board 30 according to the third embodiment is considered by way of example, and can be changed appropriately. For example, a plurality of electronic elements 33 may be mounted on the same wiring board 31. Furthermore, the electronic element 33 may be mounted not only on the main surface S7 of the wiring board 31 but also on a main surface on the side opposite to the main surface S7. Furthermore, the package component 20 as in the second embodiment may be mounted instead of or in addition to the electronic element 33.

In the third embodiment, the electronic element 33 may be sealed with a synthetic resin from the outside. In this case, the synthetic resin may be present outside the electronic element 33 covered with the protective film 16, or the protective film 16 may be present so as to cover the synthetic resin with which the electronic element 33 is sealed.

In the third embodiment, the solder resist 32 as a sealing material may be omitted. In this case, the protective film 16 directly covers the main surface S7 of the board body 31A. In addition, in this modification example, the surface roughness of the outer surface S2 of the organic film 16A is preferably smaller than the surface roughness of the main surface S7 of the board body 31A, which is the surface covered with the organic film 16A of the protective film 16 with the surface in contact with the organic film 16A.

Regarding the fourth embodiment, the above-mentioned techniques related to the protective film 16 may be applied to an element that is different from the crystal oscillator 40 as long as the metal cap 43 is joined to the ceramic board 41.

Regarding each of the embodiments, the part covered with the protective film 16 can be changed appropriately. For example, in the first embodiment, the protective film 16 may cover only the outer surface of the base body 12, or may cover only the outer surface of the external terminal 13. Further, like the boundary BL in each of the embodiments, the boundary part between different members is preferably covered with the protective film 16.

### Supplementary Note

The technical idea that can be understood from the embodiments and modification examples mentioned above will be described.
[1] An electronic module including a specific component; an organic film covering an outer surface of the specific component and containing an organic constituent as a main constituent; and a first barrier film covering the organic film and containing an inorganic constituent as a main constituent. A film thickness of the first barrier film has a minimum value of 15 nm or more, and the film thickness of the first barrier film has a maximum value of 65 nm or less.
[2] The electronic module according to [1], in which the specific component includes, as a part of the outer surface, a first plane and a second plane adjacent to the first plane and extending in a direction intersecting the first plane, and the organic film and the first barrier film cover a ridge part between the first plane and the second plane.
[3] The electronic module according to [1] or [2], including a sealing material including a synthetic resin between the specific component and the organic film.
[4] The electronic module according to [3], in which the specific component includes a metal member, the sealing material covers a part of an outer surface of the metal member, and the organic film and the first barrier film cover a boundary between a part of the metal member covered with the sealing material and a part of the metal member that is not covered with the sealing material.
[5] The electronic module according to any one of [1] to [4], in which the average film thickness of the first barrier film is 50 nm or less and is smaller than the average film thickness of the organic film.
[6] The electronic module according to any one of [1] to [5], further including a second barrier film covering an outer surface of the first barrier film.
[7] The electronic module according to any one of [1] to [6], in which an outer surface of the organic film is smaller in surface roughness than a surface covered with the organic film, with the surface in contact with the organic film.
[8] The electronic module according to any one of [1] to [5], in which the specific component further includes a first member and a second member joined to the first member with an adhesive interposed therebetween, and the organic film and the first barrier film cover the first member, the second member, and the adhesive.
[9] A method for manufacturing an electronic module, the method including a first film formation step of forming an organic film containing an organic constituent as a main constituent on an outer surface of a specific component; and a second film formation step of forming a first barrier film containing an inorganic constituent as a main constituent on an outer surface of the organic film by an atomic layer deposition method. In the second film formation step, the first barrier film is formed such that a film thickness of the first barrier film has a minimum value of 15 nm or more, and such that the film thickness of the first barrier film has a maximum value of 65 nm or less.
[10] The method for manufacturing an electronic module according to [9], further including a third film formation step of forming a second barrier film containing parylene as a main constituent on an outer surface of the first barrier film by chemical vapor deposition method.

What is claimed is:

1. An electronic module comprising:
a specific component;
an organic film covering an outer surface of the specific component and including an organic constituent as a main constituent; and
a first barrier film directly covering the organic film and including an inorganic constituent as a main constituent,
wherein a film thickness of the first barrier film has a minimum value of 15 nm or more, and the film thickness of the first barrier film has a maximum value of 65 nm or less.

2. The electronic module according to claim 1, wherein
the specific component includes, as a part of the outer surface, a first plane and a second plane adjacent to the first plane and extending in a direction intersecting the first plane, and
the organic film and the first barrier film cover a ridge part between the first plane and the second plane.

3. The electronic module according to claim 1, further comprising:
a sealing material including a synthetic resin as a main constituent between the specific component and the organic film.

4. The electronic module according to claim 3, wherein
the specific component includes a metal member,
the sealing material covers a part of an outer surface of the metal member, and
the organic film and the first barrier film cover a boundary between a part of the metal member covered with the sealing material and a part of the metal member that is not covered with the sealing material.

5. The electronic module according to claim 1, wherein
an average film thickness of the first barrier film is 50 nm or less and is smaller than an average film thickness of the organic film.

6. The electronic module according to claim 1, further comprising:
a second barrier film covering an outer surface of the first barrier film.

7. The electronic module according to claim 1, wherein
an outer surface of the organic film is smaller in surface roughness than a surface covered with the organic film, with the surface in contact with the organic film.

8. The electronic module according to claim 1, wherein
the specific component further includes a first member and a second member joined to the first member with an adhesive interposed therebetween, and
the organic film and the first barrier film cover the first member, the second member, and the adhesive.

9. A method for manufacturing an electronic module, the method comprising:
forming an organic film including an organic constituent as a main constituent on an outer surface of a specific component; and
forming a first barrier film including an inorganic constituent as a main constituent on an outer surface of the organic film by an atomic layer deposition method,
wherein in the forming of the first barrier film, the first barrier film is formed such that a film thickness of the first barrier film has a minimum value of 15 nm or more, and such that the film thickness of the first barrier film has a maximum value of 65 nm or less.

10. The method for manufacturing an electronic module according to claim 9, further comprising:
forming a second barrier film including parylene as a main constituent on an outer surface of the first barrier film by a chemical vapor deposition method.
